(19) United States
(12) Patent Application Publication
(10) Pub. No.: US 2002/0182823 A1
(43) Pub. Date: Dec. 5, 2002

(54) Wafer oxidation reactor and a method for forming a semiconductor device

(76) Inventors: Noriyuki Yokouchi, Tokyo (JP); Natsumi Ueda, Tokyo (JP); Yasumasa Sasaki, Tokyo (JP); Fumio Koyama, Tokyo (JP); Kenichi Iga, Tokyo (JP)

Correspondence Address: KNOBBE MARTENS OLSON & BEAR LLP, 2040 MAIN STREET, FOURTEENTH FLOOR, IRVINE, CA, 91614, US

(21) Appl. No.: 10/007,054

(22) Filed: Dec. 3, 2001

(30) Foreign Application Priority Data
Apr. 18, 2001 (JP) 2001-119711
Aug. 13, 2001 (JP) 2001-245172

(51) Int. Cl. H01L 21/76; H01L 21/31; H01L 21/469; C23C 16/00

(52) U.S. Cl. 438/410; 438/768; 118/725

(57) ABSTRACT

A wafer stage having a built-in heater therein mounts a heat conductive disk which mounts thereon an object wafer having an AlAs layer therein. The heat conductive disk has a thermal conductivity equal to or higher than 100 watts/K/meter. The Al-oxidized area in the AlAs layer has excellent in-plane uniformity for the width thereof due to desirable heat distribution of the wafer caused by the heat conductive disk.

### BACKGROUND OF THE INVENTION

(a) Field of the Invention

The present invention relates to a wafer oxidation system and, more particularly, to a wafer oxidation system suitably used for selective oxidation of an Al-containing semiconductor layer to obtain a current confinement structure formed by an Al-oxidized area and an Al-nonoxidized area in the Al-containing semiconductor layer. The present invention also relates to a method for forming a semiconductor device having such a current confinement structure.

(b) Description of the Related Art

In order to raise the current efficiency of the semiconductor laser device to lower the threshold current thereof, a current confinement structure is generally used for confining the current injection area in the semiconductor laser device. The current confinement structures known heretofore include a first confinement structure using a reverse bias applied to a p-n junction of the laser device, a second confinement structure using highly-resistive region formed by an ion-implantation, and a third confinement structure using an Al-oxidized area in an Al-containing layer such as AlAs layer. The Al-oxidized area is generally obtained by selective oxidation of the Al component of a portion of the Al-containing semiconductor layer.

The third confinement structure, i.e., oxidation confinement structure has an excellent current confinement function, can be formed by a relatively simple process, and thus is increasingly employed for the semiconductor laser device.

A wafer oxidation system having a combination of a vapor mass flow controller (LMFC) and an associated vaporizer is proposed for oxidation of the AlAs layer in a surface emitting semiconductor laser device (Jpn.J.Appl.Phys. 39, vol. 6A, pp3468, 2000). It is recited in the publication that the wafer oxidation system has an excellent reproducibility as well as an excellent controllability for the width of the configured Al-oxidized area.

However, in our experiments conducted, the wafer oxidation system recited in the publication exhibited only limited in-plane uniformity for the width of the Al-oxidized area over the entire wafer surface. The limited in-plane uniformity of the width of the Al-oxidized area in the Al-containing layer may lower the in-plane uniformity of the device characteristics of the product laser devices over the wafer surface.

Although the surface emitting semiconductor laser device is exemplified in the above description of the Al-oxidized area, the problem of the limited in-plane uniformity of the width of the Al-oxidized area is common to general semiconductor devices which are fabricated by using the selective oxidation of an Al-containing semiconductor layer to form the current confinement structure.

### SUMMARY OF THE INVENTION

In view of the above, it is an object of the present invention to provide a wafer oxidation system to be used for selective oxidation of an Al-containing semiconductor layer to obtain an Al-oxidized area in a current confinement structure.

It is another object of the present invention to provide a method for fabricating a semiconductor device having a current confinement structure formed by oxidation of an Al-containing semiconductor layer.

The present invention provides, in one aspect thereof, a wafer oxidation system including an oxidation reactor, and a wafer stage rotatably received therein and having a top surface for mounting thereon an object wafer, the wafer stage having a heater therein and mounting thereon a heat conductive disk having a diameter higher than a diameter of the object wafer, the heat conductive disk having a thermal conductivity equal to or higher than 100 watts/K/meter and being sandwiched between the object wafer and the top surface.

The present invention also provides, in another aspect thereof, a wafer oxidation system including an oxidation reactor, and a wafer stage rotatably received therein and having a top surface for mounting thereon an object wafer, the wafer stage having a heater therein, the top surface having a thermal conductivity equal to or higher than 100 watts/K/meter.

The present invention also provides, in another aspect thereof, a method including the steps of forming an Al-containing compound semiconductor layer overlying a substrate, selectively oxidizing the Al-containing compound semiconductor layer by using a heater installed in a wafer stage to form an Al-oxidized area and an Al-nonoxidized area in the Al-containing compound semiconductor layer, the wafer stage mounting thereon a heat conductive disk having a thermal conductivity equal to or higher than 100 watts/K/meter and sandwiched between the object wafer and the wafer stage, and forming a semiconductor device having a current confinement structure formed by the Al-oxidized area and the Al-nonoxidized area.

In accordance with the present invention, the semiconductor device formed by the method and the oxidation system of the present invention has excellent in-plane uniformity for the width of the Al-oxidized area, whereby the semiconductor devices have excellent uniformity for the device characteristics.

The above and other objects, features and advantages of the present invention will be more apparent from the following description, referring to the accompanying drawings.

### BRIEF DESCRIPTION OF THE DRAWINGS

FIG. 1 is a schematic sectional view of an oxidation system according to an embodiment of the present invention.

FIG. 2 is a detailed sectional view of the wafer stage shown in FIG. 1.

FIG. 3A is a sectional view of a sample of the layer structure before oxidation of an AlAs layer.

FIG. 3B is a sectional view of the sample of FIG. 1A after oxidation of the AlAs layer.

FIG. 4 is graph showing a profile of the widths of the oxidized areas in samples of layer structure obtained by sample disks.

FIG. 5 is a sectional view of a surface emitting semiconductor laser device having a current confinement structure using an Al-oxidized layer and formed by a method according to an embodiment of the present invention.

### PREFERRED EMBODIMENTS OF THE INVENTION

Before describing a preferred embodiment of the present invention, the experiments conducted for the present invention will be described for a better understanding of the present invention.

The inventors noted the fact that oxidation of a semiconductor material is significantly affected by the temperature during the oxidation process. The inventors first considered that the degraded uniformity of the width of the oxidized area was due to the non-uniformity of the temperature distribution in the wafer during the oxidation process. Thus, an oxidation reactor having an excellent uniformity for the temperature distribution within the oxidation reactor was used in the experiments for improvement of the in-plane uniformity of the width of the oxidized area. However, the experiments did not reveal expected results.

Then, the inventors used a disk or disk made of a material having an excellent thermal conductivity, i.e., heat conductive disk, which was interposed between the wafer stage and the object wafer, for improvement of the in-plane uniformity for the width of the Al-oxidized area. The samples of the disk (sample disk) used therein included a silicon substrate having a thickness of 500 μm, a pyrolytic boron nitride (PBN) disk having a thickness of 1 mm, a graphite disk having a thickness of 1 mm, a stainless steel disk having a thickness of 1 mm, a copper disk having a thickness of 1 mm, a silicon carbide disk having a thickness of 500 μm, and a sapphire substrate having a thickness of 300 μm. Each sample disk was of a circular shape having a diameter of 85 mm. The wafer stage had a diameter of 100 mm and each wafer had a diameter of 75 mm. Samples of layer structure having similar configurations were respectively subjected to selective oxidation using those sample disks, for evaluation of the uniformity of the width of the oxidized area for each of the sample disks.

Each sample of the layer structure was formed by the steps of growing a 100-nm-thick AlAs layer on a GaAs substrate, and growing a 1-μm-thick GaAs layer thereon. The samples of the layer structure before the oxidation are shown in FIG. 3A in cross section, whereas the samples of layer structure after the oxidation are shown in FIG. 3B in cross section. Each sample had a cleaved surface 90 from which the oxidation proceeds. The layer structure shown in FIG. 3B had a pair of stripe Al-oxidized areas 88 in the AlAs layer 82 adjacent to the cleaved surfaces 90 and an Al-nonoxidized area 86 sandwiched between the pair of Al-oxidized areas 88 after the selective oxidation. Each sample of the layer structure was cleaved to expose the cleaved surface 90 just before the selective oxidation. The selective oxidation was conducted as follows.

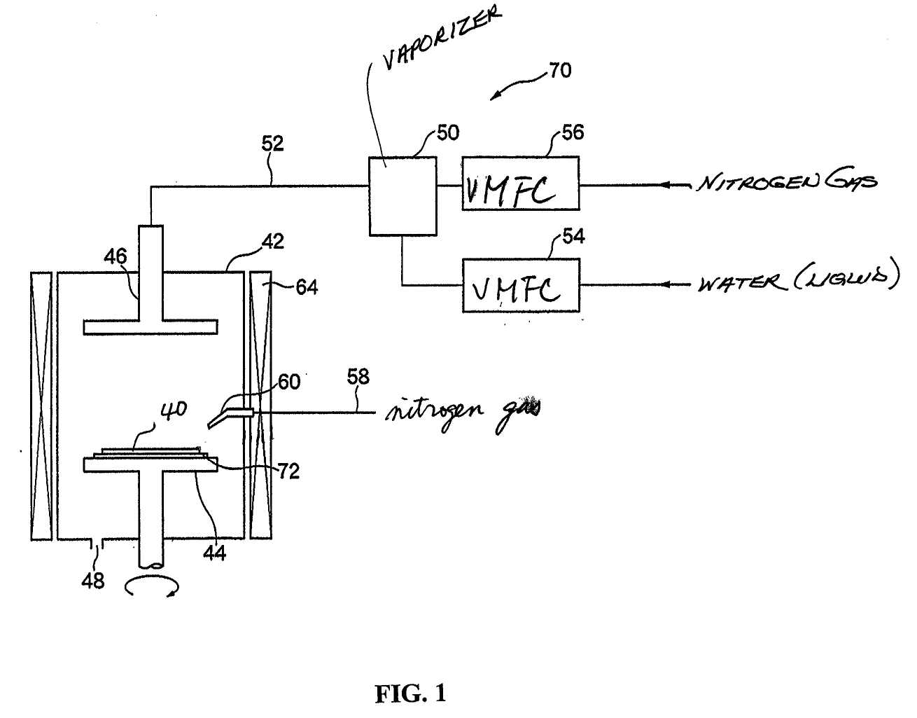

Referring to FIG. 1, each sample of the layer structure shown as a wafer 40 was mounted on a sample disk (sample tray) heated up to a temperature of 150 degrees C. and placed on the wafer stage, which was located in an ordinary oxidation reactor 42. The air inside the oxidation reactor 42 was completely replaced with nitrogen gas. Subsequently, water is supplied to a vaporizer 50 at a flow rate of 20 grams/hour via a vapor mass flow controller 54. The water thus supplied was completely evaporated, mixed with nitrogen gas supplied at a flow rate of 20 liters/minute, and then introduced into the oxidation reactor 42.

Subsequently, the sample layer structure 40 is heated by heaters 62 and 64 for three minutes up to a temperature of 400 degrees C., and maintained at the same temperature for ten minutes. After the heated sample of the layer structure was mounted on the wafer stage 44 via the sample disk 72, the wafer stage 44 was rotated at a rotational speed of 10 rotations/minute, for exposing the sample layer structure 40 to a uniform steam spray.

After raising the temperature of the sample layer structure 40 up to 400 degrees C. and maintaining the same temperature for ten minutes, the introduction of steam was stopped. Thereafter, nitrogen gas was introduced into the oxidation rector 42 at a flow rate of 20 liters/minute for rapid cooling of the sample of the layer structure. These steps are conducted for each sample disk 72.

After the oxidation, the samples of layer structure had the structure shown in FIG. 3B. These samples were subjected to measurements of the width of the oxidized area 88 extending along the cleaved surface 90, the results of which are shown in Table 1.

TABLE 1

| Material of Disk | Uniformity | Thermal Conductivity of Disk |
|---|---|---|
| Silicon | ±1.0 μm | 145 W/K/m |
| PBN | ±3.0 μm | 65 W/K/m |
| Graphite | ±0.5 μm | 140 W/K/m |
| Stainless Steel | ±2.0 μm | 20 W/K/m |
| Copper | ±0.5 μm | 400 W/K/m |
| Silicon Carbide | ±0.5 μm | 200 W/K/m |
| Sapphire | ±1.5 μm | 45 W/K/m |

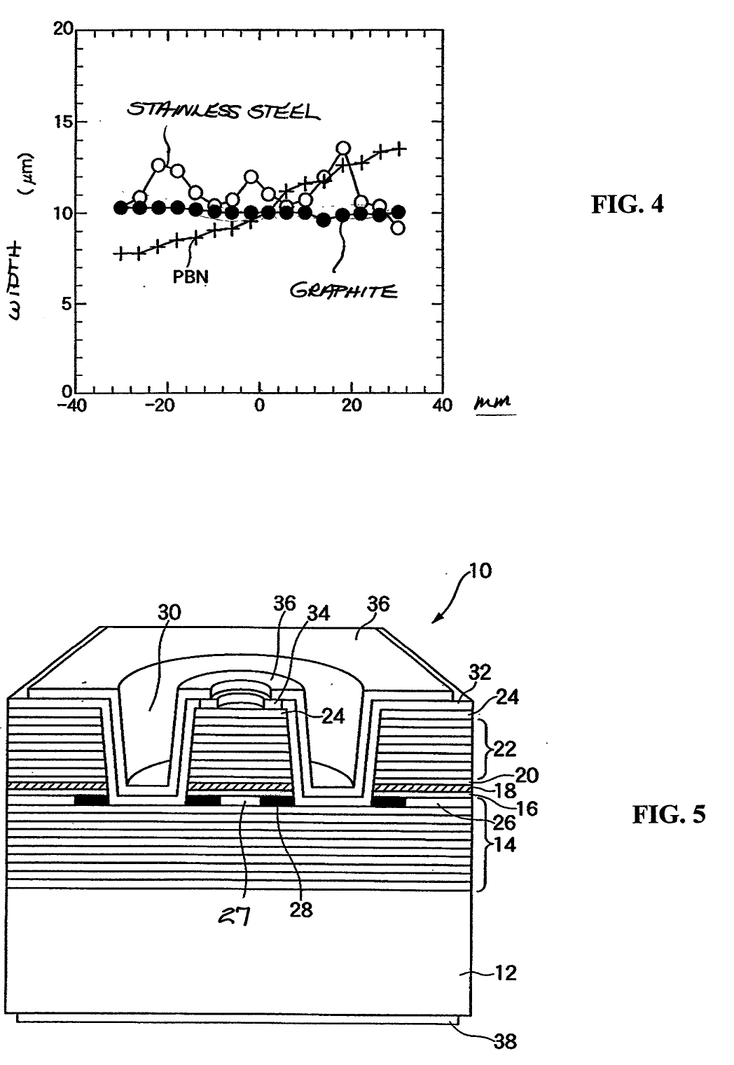

FIG. 4 shows the results of the experiments for the sample disks made of stainless steel, PBN and graphite. In FIG. 4, the distance of the location (mm) with respect to the central point of the cleaved surface in the lateral direction is plotted on abscissa against the width of the stripe oxidized area plotted on ordinate for the location. The width of the oxidized area is measured from the cleaved surface to the boundary between the oxidized area and the non- oxidized area. The locations are selected at every four millimeters.

As understood from FIG. 4, the width obtained for the graphite disk resided within ±0.5 μm, which indicated excellent uniformity. On the other hand, the widths obtained for the stainless steel disk and PBN disk resided within ±2.0 μm and ±3.0 μm, respectively, which indicated poor uniformity.

From the experiments, it was confirmed that the sample disks each having a thermal conductivity equal to or higher than 100 watts/K/meter, i.e., graphite disk, copper disk and silicon carbide disk provided excellent uniformity. Thus, the following conclusion could be obtained.

The width of the oxidized area at each location of the sample layer structure is determined by the temperature of the location and the amount of the steam supplied thereto. In the above experiments, since the sample layer structure was rotated, the amount of steam supplied was considered generally constant for the locations. Thus, it was considered that the uniformity of the oxidized area in the experiment was determined by the temperature distribution on the sample disk.

The temperature distribution on the sample disk was such that temperature dispersion for the locations of the sample layer structure was sufficiently low after the temperature reached 400 degrees C. due to the heat convection caused by the steam and nitrogen gas within the oxidation reactor 42. Thus, it was considered that the non-uniformity of the width of the oxidized area resulted from the temperature distribution caused by the thermal conductivity of the sample disk during the process wherein the temperature of the layer structure was raised up to 400 degrees C.

In the above experiments, the silicon substrate provided relatively poor uniformity of the oxidation width, although silicon itself has a higher thermal conductivity. This is considered due to a silicon oxide film having a lower thermal conductivity and formed on the surface of the silicon substrate before or during the oxidation process. It was confirmed that a silicon substrate coated with graphite, copper or silicon carbide film provided excellent uniformity for the width of the oxidized area.

The thickness of the thermal conductive disk preferably provides a sufficient mechanical strength for the thermal conductive disk. Instead of provision of the thermal conductive disk, the wafer stage may have a higher thermal conductivity, i.e., equal to or higher than 100 watts/K/meter at least on the top surface of the wafer stage.

Now, the present invention is more specifically described based on a preferred embodiment thereof In the drawings, similar constituent elements are designated by similar reference numerals.

Referring again to FIG. 1, the wafer oxidation system, generally designated by numeral 70, according to an embodiment of the present invention includes the oxidation reactor 42 having a closed cylindrical shape, the wafer stage 44 received in the oxidation reactor 42 at the central, bottom portion thereof for rotating an object wafer 40 in a horizontal plane, a main nozzle 46 disposed at the top portion of the oxidation reactor 42, and a vacuum pump (not shown) for evacuating the air inside the oxidation reactor 42 via an exhaust port 48. The wafer stage 44 is rotated around the central axis thereof for a uniform spray of steam toward the wafer 40.

The main nozzle 46 is associated with a vaporizer 50 connected thereto via a tube 52. Water is introduced to the vaporizer 50 via the vapor mass flow controller 54, and evaporated in the vaporizer 50. The evaporated water or steam is mixed with the nitrogen gas introduced to the vaporizer 50 via the vapor mass flow controller 56, and passes the tube 52 to be ejected through the main nozzle 46 for spray in the oxidation reactor 42.

The oxidation rector 42 is also provided with an auxiliary nozzle 60 connected to a supply tube 58 for supplying nitrogen gas for cooling use. The cooling nitrogen gas is ejected downward through the auxiliary nozzle 60 toward the wafer 40 for cooling the same.

A heater 64 is provided for surrounding the oxidation reactor 42. The main nozzle 46 is also provided with another heater (not shown) for heating the mixture of steam and nitrogen gas and maintaining the wafer on the wafer stage 44 at a desired temperature.

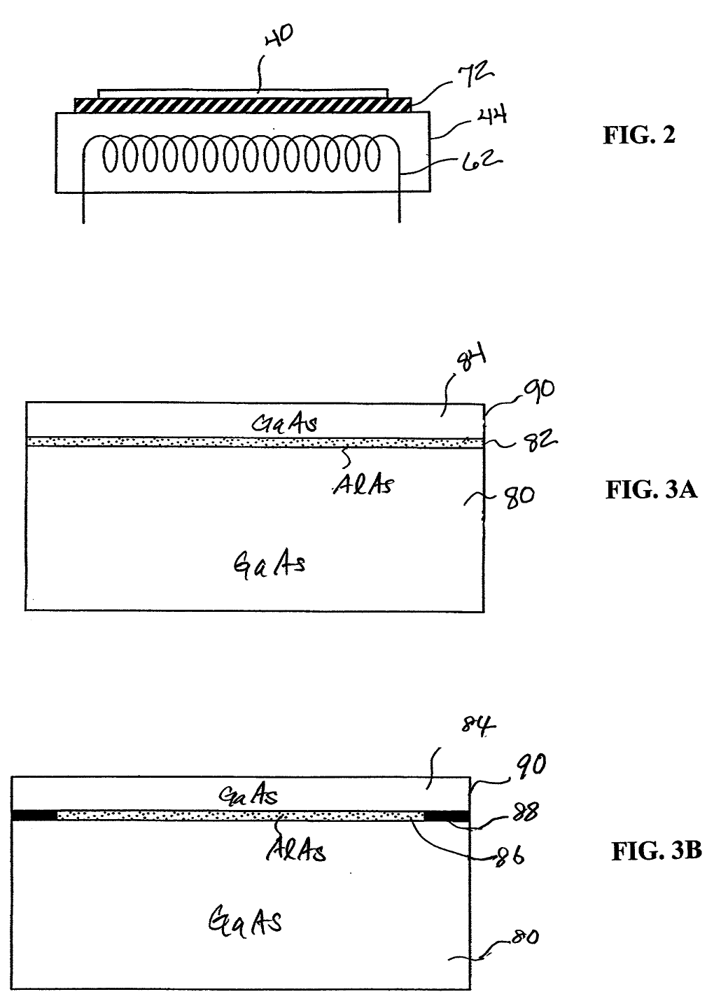

FIG. 2 shows the detail of the wafer stage 44, which includes a built-in heater 62 for heating the wafer 40 mounted on the wafer stage 44. A heat conductive disk 72 having a thermal conductivity equal to or higher than 100 watts/K/meter is interposed between the wafer 40 and the top surface of the wafer stage 44. The heat conductive disk 72 is made of graphite and assumes a disk shape having a thickness of 1 mm and a diameter of 85 mm. The heat conductive disk 72 is adhered onto the top surface of the wafer stage 44, which has a diameter of 100 mm. The wafer has a diameter of 75 mm in this example.

Referring to FIG. 5, there is shown a surface emitting semiconductor laser device fabricated by a method according to an embodiment of the present invention. The semiconductor laser device generally designated by numeral 10 includes a p-type GaAs (p-GaAs) substrate 12, and a layer structure formed on the p-GaAs substrate 12. The layer structure includes, consecutively as viewed from the bottom, a p-type lower reflecting mirror 14 having 35.5 pairs of p-Al_{0.2}Ga_{0.8}As/p-Al_{0.9}Ga_{0.1}As layers, an undoped Al_{0.3}Ga_{0.7}As lower cladding layer 16, a MQW active layer structure 18, an undoped Al_{0.3}Ga_{0.7}As upper cladding layer 20, an n-type upper reflecting mirror 22 having 25 pairs of n-Al_{0.2}Ga_{0.8}As/n-Al_{0.9}Ga_{0.1}As layers, and an n-GaAs cap layer 24.

The top layer of the p-type lower reflecting mirror 14 which is most adjacent to the active layer 18 is implemented by an AlAs layer 26 instead of the n-Al_{0.9}Ga_{0.1}As layer. The AlAs layer 26 includes an Al-nonoxidized area 27 as a current injection area and an Al-oxidized area 28 as a current confinement area, thereby forming a current confinement structure. The MQW active layer structure 18 includes a plurality of (for example, three in this example) GaAs quantum well layers and associated Al_{0.2}Ga_{0.8}As barrier layers.

Among the layer structure, the upper reflecting mirror 22, the upper cladding layer 20, the MQW active layer structure 18, the lower cladding layer 16, and the AlAs layer 26 are configured by photolithographic and etching steps to form an annular groove 30 having a width of 30 μm. The annular groove 30 defines a circular mesa post structure within the inner wall thereof, the mesa post structure having a diameter of 40 μm at the central portion thereof

Except for the top of the mesa post structure, a SiNₓ film 32 is provided as a protective film over the top of the layer structure including the inner wall of the groove 30. In addition, an annular electrode or n-side electrode 34 defining a central opening having a diameter of 10 μm for laser emission is formed on the SiNx film 32 except for the top of the mesa post structure. A Ti/Pt/Au pad 36 is formed on the n-side electrode 34 for electrical connection. The bottom surface of the GaAs substrate 12 is polished to obtain a final thickness of 100 μm for the GaAs substrate 12, and a p-side electrode 38 is formed on the polished bottom surface of the GaAs substrate 12.

The surface emitting semiconductor laser device of FIG. 5 is fabricated as follows. First, 35.5 pairs of p-Al_{0.2}Ga_{0.8}As/p-Al_{0.9}Ga_{0.1}As layers are grown on a GaAs substrate 12 to form a lower reflecting mirror 14 by using a metal organic CVD (MOCVD) technique. The top layer of the lower reflecting mirror 14 is implemented by an AlAs layer 26 instead of a p-Al_{0.9}Ga_{0.1}As layer.

Subsequently, by using a MOCVD technique, a lower cladding layer 16, a MQW active layer 18 and an upper cladding layer 20 are consecutively grown thereon. Then, 25 pairs of n-Al_{0.2}Ga_{0.8}As/n-Al_{0.9}Ga_{0.1}As layers are grown to form an upper reflecting mirror 22, followed by growth of a cap layer 24 on the top Al_{0.2}Ga_{0.8}As layer of the upper reflecting mirror 22, thereby obtaining the layer structure on the GaAs substrate 12.

Thereafter, a SiNₓ film (not shown) is deposited using a plasma-enhanced CVD technique, followed by forming a photoresist film thereon. The photoresist film is subjected to patterning using a photolithographic and etching technique to form a photoresist mask, which defines a circular pattern having a diameter of about 40 μm.

The SiNₓ film is then patterned by a reactive ion etching (RIE) technique using CF₄ gas as an etching gas and the photoresist mask as an etching mask. By using a RIE etching technique using the same photoresist mask, the layer structure is also patterned until the top layer of the lower reflecting mirror 14 underlying the AlAs layer 26 is exposed, thereby forming a cylindrical mesa post.

After removing the photoresist mask, the layer structure configured as the cylindrical mesa post is introduced in the wafer oxidation system 70 shown in FIG. 1, for oxidizing the AlAs layer 26 to form an Al-oxidized area 28 therein acting as a current confinement area. The heat conductive disk 72 heated at 150 degrees C. is interposed between the wafer 40 and the wafer stage 44.

After mounting the wafer 40 on the heat conductive disk 72, the air inside the oxidation reactor 42 is substantially completely replaced by nitrogen gas, followed by supplying water to the vaporizer 50 at a flow rate of 20 grams/hour via the vapor mass flow controller 54. The water is evaporated in the vaporizer 50, mixed with the nitrogen gas supplied to the vaporizer 50 through the vapor mass flow controller 56 at a flow rate of 20 grams/minute, and then introduced into the oxidation reactor 42.

Subsequently, the temperature of the wafer 40 is raised up to 400 degrees C. in about three minutes by the heater 62. Then, the temperature of the wafer 40 is maintained at 400 degrees C. for 10 minutes. After mounting the wafer 40 on the wafer stage 44 via the heat conductive disk 72, the wafer stage 44 is rotated at a rotational speed of 10 rotations/minute, thereby exposing the wafer to a uniform spray of steam. The wafer is maintained at 400 degrees C. for 10 minutes, then the introduction of steam is stopped, and nitrogen gas is introduced at a flow rate of 20 liters/minute from the auxiliary nozzle 60 for rapid cooling of the wafer 40, whereby the oxidation process is finished.

A sample obtained by the process as described above included an AlAs layer 26 including an Al-oxidized area 28 having a width of about 10 μm with excellent in-plane uniformity of the width.

In the above embodiment, the heat conductive disk 72 is made of a single material. However, the heat conductive disk 72 may be made of a plurality of materials so long as the thermal conductivity thereof is equal to or higher than 100 watts/K/meter. For example, the heat conductive disk 72 may be made of a silicon substrate coated with graphite or silicon carbide. The graphite suppresses oxidation of the silicon substrate itself whereas the silicon carbide improves the heat resistance of the silicon substrate.

In the above embodiment, a surface emitting semiconductor laser device having a GaAs MQW active structure as the luminescence layers is exemplified. However, the present invention may be applied to any semiconductor device so long as the semiconductor device has an Al-containing layer which is selectively oxidized to form an Al-oxidized area therein. For example, the present invention may be applied to another surface emitting semiconductor laser device having a GaInNAs QW active layer or layers having an emission wavelength of 1.3 μm, or an edge emitting semiconductor laser device having an Al-oxidized layer in an AlAs super-lattice structure.

Since the above embodiments are described only for examples, the present invention is not limited to the above embodiments and various modifications or alterations can be easily made therefrom by those skilled in the art without departing from the scope of the present invention.

What is claimed is:

1. A wafer oxidation system comprising:
a stage having a surface;
a material mounted on said stage, wherein said material has a thermal conductivity of at least about 100 watts/K/meter; and
an oxidizing system operable to selectively oxidize semiconductor material in said wafer to form a current confinement structure in said semiconductor material.

2. The system of claim 1, wherein said thermally conductive material consists essentially of graphite.

3. The system of claim 2, wherein said thermally conductive material has a thickness of approximately one millimeter.

4. The system of claim 1, wherein said thermally conductive material consists essentially of copper.

5. The system of claim 1, wherein said thermally conductive material consists essentially of silicon carbide.

6. The system of claim 1, wherein said thermally conductive material comprises a silicon substrate coated with graphite, copper or silicon carbide.

7. A wafer oxidation system for selectively oxidizing an Aluminum containing semiconductor layer of a semiconductor wafer to create a current confinement structure, the system comprising:
an oxidation reactor comprising a wafer stage having a top surface with a thermal conductivity of at least 100 watts/K/meter, wherein said semiconductor wafer is supported by said top surface of said wafer stage, whereby said oxidation reactor is operable to selectively oxidize said Aluminum containing layer to create an Aluminum oxidized area and an Aluminum non-oxidized area such that said Aluminum oxidized area is substantially uniformly disposed around the perimeter of said Aluminum non-oxidized area.

8. A wafer oxidation system comprising:
an oxidation reactor, and
a wafer stage comprising a surface having a thermal conductivity equal to or higher than 100 watts/K/meter.

9. The system of claim 8, wherein said surface is a top surface of said wafer stage.

10. The system of claim 8, wherein said surface is a top surface of a disc mounted on said wafer stage.

11. The system of claim 8, wherein said surface consists essentially of graphite, copper, or silicon carbide.

12. A wafer oxidation system comprising:
a source of oxidizer;
a layer having a thermal conductivity of at least 100 watts/K/meter for supporting said wafer during oxidation.

13. A semiconductor wafer made with a method comprising:
mounting a thermally conductive material having a thermal conductivity of at least 100 watts/K/meter on a wafer stage in an oxidation chamber;
mounting said semiconductor wafer on said thermally conductive material;
dispensing a mixture of water vapor and nitrogen gas in to said oxidation chamber so that said semiconductor wafer is exposed to a uniform spray of said mixture.

14. The wafer of claim 13, wherein said thermally conductive material consists essentially of graphite.

15. The wafer of claim 14, wherein said thermally conductive material has a thickness of approximately one millimeter.

16. The wafer of claim 13, wherein said thermally conductive material consists essentially of copper.

17. The wafer of claim 13, wherein said thermally conductive material consists essentially of silicon carbide.

18. A method of forming a semiconductor wafer having an oxidized portion and a non-oxidized portion, the method comprising:
placing said semiconductor wafer on a thermally conductive material in an oxidation reactor having a thermal conductivity of at least about 100 watts/K/meter;
exposing said semiconductor wafer to an oxidizing mixture.

19. The method of claim 18, wherein said oxidizing mixture comprises a mixture of heated water vapor and nitrogen gas.

20. The method of claim 19, wherein said oxidizing mixture is dispensed at least a rate of about 20 grams per hour.

21. The method of claim 18, further comprising:
rotating said thermally conductive material at a rate of approximately ten rotations per minute.

22. A method of forming a semiconductor laser having a current confinement structure comprising an oxidized portion and a non-oxidized portion, the method comprising:
placing said semiconductor laser on a wafer stage in an oxidation reactor, at least a portion of said wafer stage having a thermal conductivity of at least about 100 watts/K/meter;
exposing said semiconductor laser to an oxidizing mixture.

23. A method of making a semiconductor laser comprising:
forming a layered structure including a lower reflecting mirror, an active layer, and an upper reflecting mirror;
mounting said layered structure on a wafer stage in an oxidation reactor having a thermal conductivity of at least about 100 watts/K/meter;
oxidizing a portion of said layered structure in said oxidation reactor forming a current confinement area including an inner non-oxidized portion and an outer oxidized portion, wherein the radial width of said oxidized portion is circumferentially uniform within about ten percent of the average radial width of said outer oxidized portion.

24. The method of claim 23, wherein said wafer stage consists essentially of one or more of graphite, copper, or silicon carbide.

25. A method for forming a current confinement structure on a semiconductor wafer comprising:
mounting a wafer to be partially oxidized on a wafer stage having a thermal conductivity of at least about 100 watts/K/meter;
heating said wafer to a substantially uniform temperature; and
exposing said wafer to an oxidizing agent so as to oxidize said wafer such that the radial width of an oxidized portion of said wafer is circumferentially uniform.

26. A method of selectively oxidizing a semiconductor wafer comprising:
mounting a thermally conductive material having a thermal conductivity of at least 100 watts/K/meter on a wafer stage in an oxidation container;
mounting said semiconductor wafer on said thermally conductive material;
dispensing a mixture of water vapor and nitrogen gas in to said oxidation container so that said semiconductor wafer is exposed to a uniform spray of said mixture.

27. An oxidizing apparatus comprising:
support means for maintaining said wafer at a substantially uniform temperature.

28. A wafer oxidation system comprising:
an oxidation reactor, and a wafer stage rotatably received therein and having a top surface for mounting thereon an object wafer, said wafer stage having a heater therein and mounting thereon a heat conductive disk having a diameter larger than a diameter of the object wafer, said heat conductive disk having a thermal conductivity equal to or higher than 100 watts/K/meter and being sandwiched between said object wafer and said top surface.

29. The wafer oxidation system as defined in claim 28, wherein said heat conductive disk includes graphite, silicon carbide, copper or silicon as a main component thereof.

30. A wafer oxidation system comprising:
an oxidation reactor, and
a wafer stage rotatably received therein and having a top surface for mounting thereon an object wafer, said wafer stage having a heater therein, said top surface having a thermal conductivity equal to or higher than 100 watts/K/meter.

31. The wafer oxidation system as defined in claim 30, wherein said top surface includes graphite, silicon carbide, copper or silicon as a main component thereof.

32. A method comprising:
forming an Al-containing semiconductor layer overlying a substrate;
selectively oxidizing said Al-containing semiconductor layer by using a heater installed in a wafer stage to form an Al-oxidized area and an Al-nonoxidized area in said Al-containing semiconductor layer, said wafer stage mounting thereon a heat conductive disk having a thermal conductivity equal to or higher than 100 watts/K/meter and sandwiched between the object wafer and said wafer stage; and
forming a semiconductor device having a current confinement structure formed by said Al-oxidized area and said Al-nonoxidized area.
